(19) United States
(12) Patent Application Publication
(10) Pub. No.: US 2017/0009340 A1
(43) Pub. Date: Jan. 12, 2017

(54) METHOD AND DEVICE FOR DISPENSING POWDER

(71) Applicant: ACHROLUX INC., Sunnyvale, CA (US)

(72) Inventors: Peiching Ling, Sunnyvale, CA (US); Dezhong Liu, Sunnyvale, CA (US)

(21) Appl. No.: 15/201,649

(22) Filed: Jul. 5, 2016

(30) Foreign Application Priority Data
Jul. 9, 2015 (TW) 104122266

(51) Int. Cl. C23C 16/442

(52) U.S. Cl. CPC C23C 16/442

(57) ABSTRACT

A method for dispensing powder includes: providing a device for dispensing powder, the device including a framework, warps connected to the framework, a trough for receiving powder, an actuating member for displacing at least one of the framework and the trough, and an action source for the powder to be detached from the warps and dispensed on an object; supplying the powder to the warps and generating an electric field for the powder to carry an electric charge and become charged powder; and providing a force, by the action source, to at least one of the framework and the warps for the charged powder to be detached from the warps, the charged powder moving dependent on the electric field and being dispensed on the object. The warps have equal amounts of charged powder carried thereon, allowing the charged powder to be distributed evenly.

### BACKGROUND

1. Technical Field

The present disclosure relates to a method for forming a uniform powder layer on a workpiece, and, more particularly, to a method and device for dispensing powder.

2. Description of Related Art

In the process of manufacturing conventional light emitting diodes (LEDs), phosphors may be dispensed or sprayed thereon. In general coating methods, it is difficult to control the amount of phosphors coated on each area of the object to be coated. As a result, the amount of the phosphor coated in each area is inconsistent, resulting in different thicknesses of the phosphor.

A conventional spraying system is shown in FIG. 1. A supplying device 1 includes a fluidizing plate 10 with a plurality of pores (not shown), a supply unit 11 provided below the fluidizing plate, and a carrier 12. The fluidizing plate 10 carries powder 8.

In use, the carrier 12 is arranged at the top of the fluidizing plate 10, the supply unit 11 supplies air from the side in order to provide the wind force A through the bottom of the fluidizing plate 10, and the wind force A brings the powder 8 upwards to the carrier 12 through the pores, such that the powder 8 is attached to the carrier 12.

However, in the conventional spraying method, the wind force A moves the powder 8 directly. Also, the wind force A blows towards the entire bottom surface of the fluidizing plate 10. However, the direction of the air flow cannot be controlled after the air passes through the pores. The direction of the wind force A after it passes through the fluidizing plate 10 is not fixed, causing turbulence. As a result, the powder 8 can neither rise uniformly and be distributed evenly on the carrier 12, nor be evenly attached to various objects 13. Therefore, the uniformity requirement for the powder 8 cannot be met.

Further, since the size of the pores on the fluidizing plate 10 is very small, the powder 8 tends to clog up these pores, and the wind force A is unable to pass through some areas of the fluidizing plate 10, which results in the unevenness of the powder 8 that are attached to the carrier 12. Therefore, the uniformity requirement for the powder 8 cannot be met.

Therefore, there is a need for a solution that addresses the aforementioned issues in the prior art.

### SUMMARY

In view of the aforementioned shortcomings of the prior art, the present disclosure provides a device for dispensing powder, which may include: a framework; a plurality of warps each having two ends combined with the framework for the warps to be positioned within the boundary of the framework; a trough for receiving powder; an actuating member for displacing at least one of the framework and the trough, allowing the warps to be positioned inside the trough and loaded with the powder inside the trough; and an action source for the powder to be detached from the warps and then dispensed on an object to be coated.

In an embodiment, the device may further include a carrier for carrying the object to be coated, and the carrier is positioned above the framework and separated from the framework.

In an embodiment, the action source acts on at least one of the framework and the warps to vibrate the powder for the powder to be detached from the warps and dispensed on the object to be coated. In an embodiment, the action source may include impact force conduction, fluid power, sound wave or ultrasound.

The present disclosure further includes a method for dispensing powder, which may include: providing the aforementioned device; supplying the powder to the warps; generating an electric field for the powder to carry an electric charge and thus become charged powder; and providing a force, by the action source, to at least one of the framework and the warps for the charged powder to be detached from the warps, wherein the charged powder moves dependent on the electric field for the charged powder to be dispensed on the object to be coated.

In an embodiment, the device further includes a carrier for carrying the object to be coated, and the carrier is positioned on top of the framework and separated from the framework.

In an embodiment, the step of supplying the powder to the warps may include displacing, by the actuating member, at least one of the framework and the trough for the warps to be positioned in the trough and loaded with the powder in the trough; and move, by the actuating member, the warps out of the trough.

With the actuating member and the warps (lines) according to the present disclosure, when the device is in use, the powder is attached to the warps, and the amounts of powder on each place of the warps are substantially the same, and a force is further applied to at least one of the framework and the warps, such that the quantities of charged powder being moved on each place of the warps are substantially the same, thereby avoiding the problem that powder cannot be uniformly coated on each LED in the prior art.

### BRIEF DESCRIPTION OF THE DRAWINGS

The present disclosure can be more fully understood by reading the following detailed description of the preferred embodiments, with reference made to the accompanying drawings, wherein:

FIG. 1 is a cross-sectional diagram illustrating a conventional powder coating device using air stream;

FIGS. 2 to 2″ are schematic diagrams illustrating a device for dispensing powder in accordance with the present disclosure in different states; and

FIGS. 3A to 3D are top-view diagrams illustrating different implementations of the distribution of a plurality of warps.

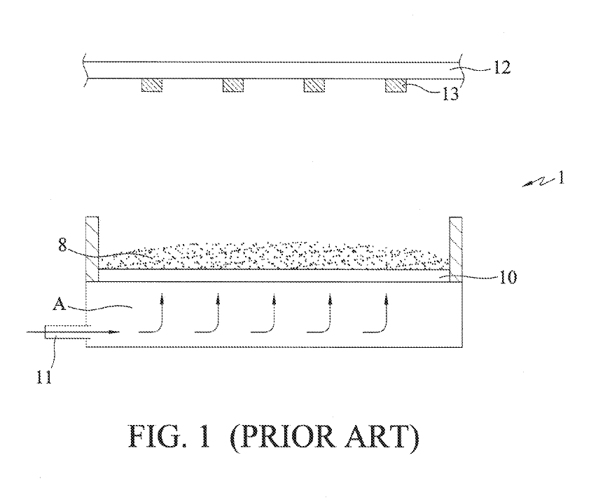

### DETAILED DESCRIPTION OF THE EMBODIMENTS

The present disclosure is described by the following specific embodiments. Those with ordinary skills in the arts can readily understand other advantages and functions of the present disclosure after reading the disclosure of this specification. The present disclosure may also be practiced or applied with other different implementations. Based on different contexts and applications, the various details in this specification can be modified and changed without departing from the spirit of the present disclosure.

It should be noted that the structures, ratios, sizes shown in the drawings appended to this specification are to be construed in conjunction with the disclosure of this specification in order to facilitate understanding of those skilled in the art. They are not meant, in any ways, to limit the implementations of the present disclosure, and therefore have no substantial technical meaning. Without affecting the effects created and objectives achieved by the present disclosure, any modifications, changes or adjustments to the structures, ratio relationships or sizes, are to be construed as fall within the range covered by the technical contents disclosed herein. Meanwhile, terms, such as “up”, “down”, “bottom”, “first”, “second”, “a” and the like, are for illustrative purposes only, and are not meant to limit the range implementable by the present disclosure. Any changes or adjustments made to their relative relationships, without modifying the substantial technical contents, are also to be construed as within the range implementable by the present disclosure.

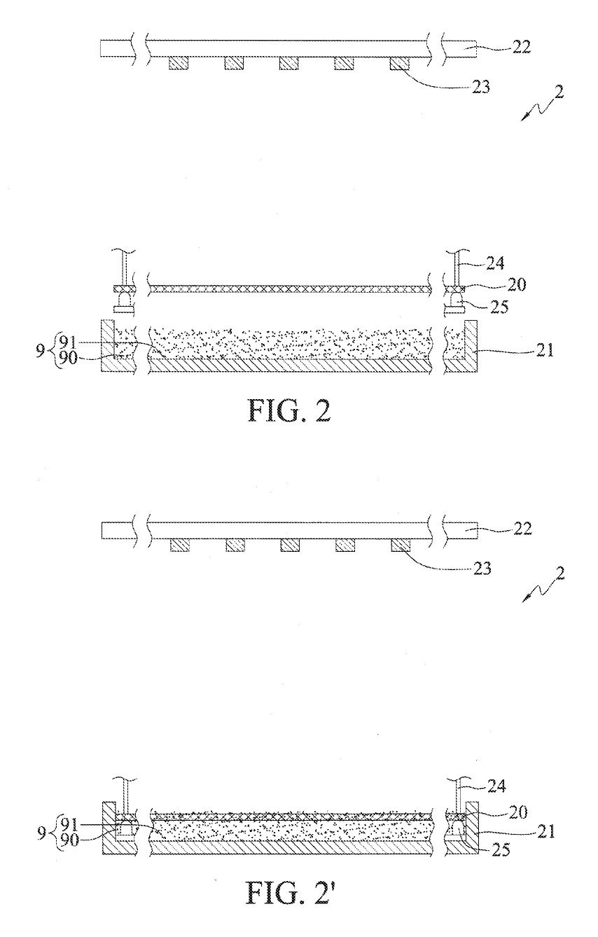

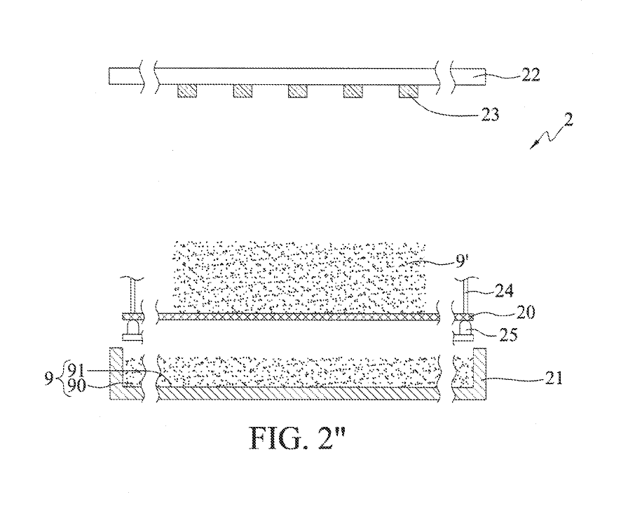

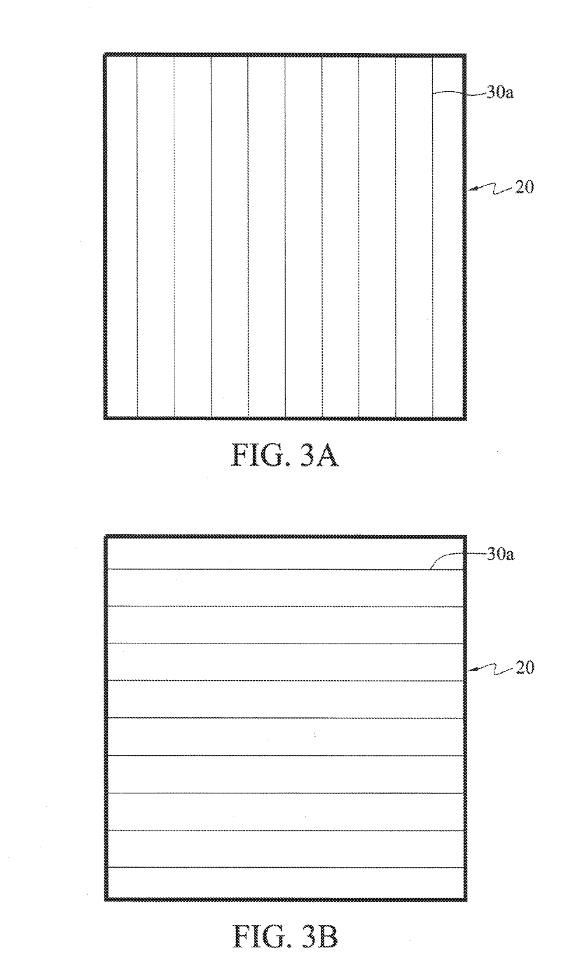

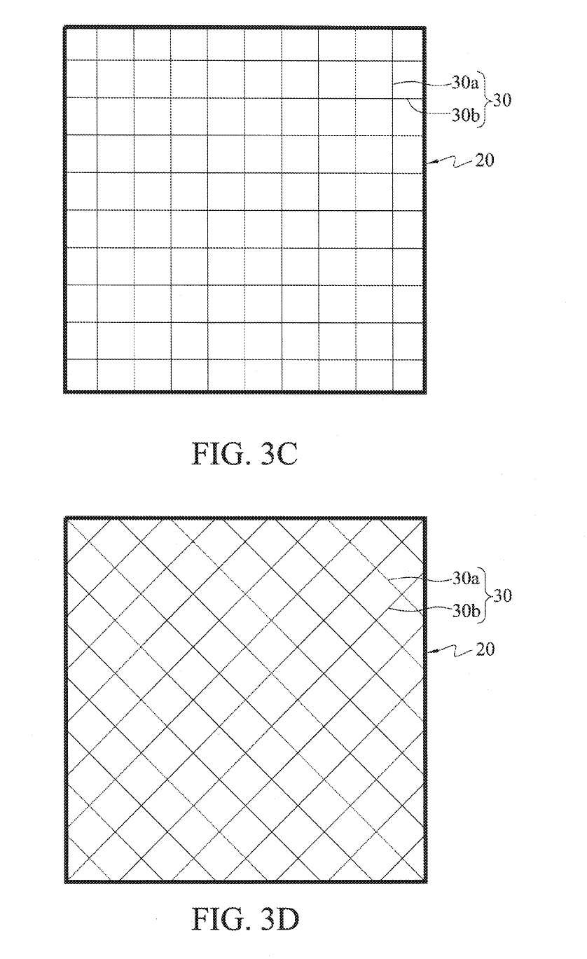

FIGS. 2 to 2″ are schematic diagrams illustrating a device for dispensing powder 2 in accordance with the present disclosure in different states. FIGS. 3A to 3D are diagrams illustrating different implementations of a plurality of warps loaded with powder.

As shown in FIG. 2, the device for dispensing powder 2 includes: a framework 20, a trough 21, an actuating member 24 and an action source 25. In an embodiment, the device for dispensing powder 2 further includes lines, such as a plurality of warps and woofs, as shown in FIGS. 3A to 3D.

Refer to FIGS. 3A to 3D for details on the lines included in the device for dispensing powder 2 according to the present disclosure. As shown in FIG. 3A, both ends of each of the warps 30a are adhered or wound onto the framework 20. Each warp 30a is within the boundary of the framework 20.

As shown in FIG. 3B, the warps 30a are distributed horizontally. It is noted that the terms “warps” and “woofs” used herein are only for describing groups of lines that are distributed in certain ways, for example, extending in the same direction within a group. Preferably, the warps 30a are evenly distributed.

As shown in FIGS. 3C and 3D, the device for dispensing powder further includes a plurality of woofs 30b. Both ends of each of the woofs 30b are combined with the framework 20, such that the warps 30b are within the boundary of the framework 20. The woofs 30b and the warps 30a form a mesh structure 30. In an embodiment, the warps 30a and the woofs 30b shown in FIG. 3D are distributed non-vertically and non-horizontally. Similarly, it is noted that the terms “warps” and “woofs” used herein are only for describing groups of lines that are distributed in certain ways, for example, extending in the same direction within a group. Preferably, the warps 30a and woofs 30b are evenly distributed. Moreover, in an embodiment the lines shown in FIG. 3A to 3D are substantially provided on the same plane.

Referring back to FIG. 2, the trough 21 is used for loading powder 9. The powder 9 may include a plurality of powder particles 90 and adhesive 91. In an embodiment, the adhesive 91 may include solid particles. The adhesive 91 may be adhered to or separated from the powder particles 90. In an embodiment, the adhesive 91 may cover the powder particles 90. The powder particles 90 may be, for example, phosphor, nano tubes, quantum dots, carbon tubes, graphene. However, the powder 9 may also include just the powder particles 90, without the adhesive 91.

The device for dispensing powder 2 may further include a carrier 22 provided above the framework 20 and is spaced apart from the framework 20. The carrier 22 can be used for receiving charged powder 9′ shown in FIG. 2″, such that a plurality of objects 23 (e.g., LEDs) to be coated can be carried on the carrier 22, and the charged powder 9′ can be formed on the objects 23.

In an embodiment, the actuating member 24 can be used for displacing the framework 20. During implementation, the actuating member 24 can be mechanically fastened to the framework 20, including, but not limited to, screwing, such that the framework 20 is displaced by moving the actuating member 24. Alternatively, the actuating member 24 may actuate the framework 20 via a movable part such as a connecting rod.

As shown in FIG. 2′, when the device for dispensing powder 2 is in use, first the actuating member 24 displaces the framework 20, then the warps 30a move into the powder 9 in the trough 21, and the powder 9 is attached to the warps 30a. Then, the actuating member 24 moves the framework 20 out of the trough 21, as shown in FIG. 2″. Alternatively, the actuating member 24 may move the trough 21 instead, such that the framework 20 is in the trough 21 or out of the trough 21.

Moreover, the device for dispensing powder 2 further includes an action source 25 that can be provided in the framework 20 (not shown), or adjacent to the framework 20, such as above or at the left or right hand side of the framework 20, or at the bottom of the framework 20 as shown in FIG. 2. The action source 25 acts on at least one of the framework 20 and the warps 30a so as to vibrate the powder 9 in such a way that it leaves the warps 30a. Alternatively, in an embodiment that includes woofs 30b, the powder 9 leaves the woofs 30b. Furthermore, the action source 25 is close to the periphery of the framework 20. Specifically, the action source 25 may include, but not limited to, ultrasound, impact force, bumps, jets of water or a device with a hook member that perturbs the lines, that is, the warps 30a and/or the woofs 30b.

Therefore, in the schematic diagram illustrating a particular operating state in FIG. 2″, the action source 25 is turned on to provide a force to at least one of the framework 20 and the warps 30a, causing the warps 30a to vibrate, which in turn, vibrate the charged powder 9′ on the warps 30a, such that the charged powder 9′ moves away from the warps 30a. The charged powder 9′ rises towards the carrier 22 as a result of the electric field. Then, the charged powder particles 90 are attached to the objects 23 to be coated through the adhesive 91. Specifically, the method for charging the powder 9 may include, after the warps 30a are moved out of the trough 21, generating an electric field between the framework 20 and the carrier 22 using a power supply, such that the powder 9 becomes charged powder 9′. For example, the warps 30a are supplied with a negative high voltage to create an electric field, and corona discharge is created by the evenly distributed plurality of warps 30a, such that the powder 9 carries electrons (i.e., negatively charged) and becomes the charged powder 9′. As a result of the electric field, the charged powder 9′ becomes more readily attached to the objects 23 to be coated. In another embodiment, the warps 30a may also carry holes (i.e., positively charged).

Therefore, once the charged powder 9′ is moved away from the warps 30a as a result of the force applied by the action source 25, the charged powder 9′ is immediately led towards the objects 23 to be coated by the electric field, and the upward force (i.e., electric field attraction) from the warps 30a to the carrier 22 is enhanced. There is no other external forces (e.g., the traditional wind force) between the warps 30a to the carrier 22, such that the direction (i.e., upwards direction) of the charged powder 9′ can be effectively controlled. This ensures the uniformity of the powder particles 90 attached on the objects 23 to be coated.

After one electrostatic adsorption coating is carried out, the majority of the powder 9 on the warps 30a is removed, and the warps 30a return to the state before the powder 9 is attached as shown in FIG. 2. If electrostatic adsorption is to be performed again, as described above, the framework 20 and the trough 21 are moved relative to each other by the actuating member 24, such that powder 9 is attached onto the warps 30a, and then the warps 30a with powder 9 attached thereon are separated from the trough 21.

With the actuating member and the warps (lines) according to the present disclosure, when the device is in use the powder is attached to the warps, the quantities of powder on each place of the warps are substantially the same, and a force is further applied to at least one of the framework and the warps, such that that the quantities of charged powder being moved on each place of the warps are substantially the same, thereby avoiding the problem that powder cannot be uniformly coated on each LED in the prior art.

Therefore, compared to the prior art, during mass production, the device for dispensing powder according to the present disclosure is able to uniformly distribute charged powder on each object to be coated, regardless of how large the ranges of actuation the lines are, thereby ensuring the uniformity of powder in each batch of products.

The above embodiments are only used to illustrate the principles of the present disclosure, and should not be construed as to limit the present disclosure in any way. The above embodiments can be modified by those with ordinary skill in the art without departing from the scope of the present disclosure as defined in the following appended claims.

What is claimed is:

1. A device for dispensing powder, comprising:
a framework;
a plurality of warps each having two ends combined with the framework for the warps to be positioned within a boundary of the framework;
a trough configured to receive the powder;
an actuating member configured to displace at least one of the framework and the trough for the warps to be positioned inside the trough and loaded with the powder inside the trough; and
an action source configured to allow the powder to be detached from the warps and dispensed on an object to be coated.

2. The device of claim 1, further comprising a carrier configured to carry the object to be coated.

3. The device of claim 2, wherein the carrier is positioned above the framework and separated from the framework.

4. The device of claim 1, wherein the actuating member is configured to move the warps out of the trough.

5. The device of claim 1, further comprising a power supply configured to generate an electric field after the warps are moved out of the trough for the powder carrying an electric charge to become charged powder.

6. The device of claim 1, wherein the action source acts on at least one of the framework and the warps to vibrate the powder for the powder to be detached from the warps.

7. The device of claim 6, wherein the action source includes impact force conduction, fluid power, sound wave or ultrasound.

8. The device of claim 1, further comprising a plurality of woofs each having two ends combined with the framework for the woofs to be positioned within the boundary of the framework.

9. The device of claim 8, wherein the woofs and the warps form a mesh structure.

10. The device of claim 8, wherein at least one of the woofs and the warps are evenly distributed.

11. A method for dispensing powder, comprising:
providing the device of claim 1;
supplying the powder to the warps;
generating an electric field for the powder to carry an electric charge and become charged powder; and
providing a force, by the action source, to at least one of the framework and the warps for the charged powder to be detached from the warps.

12. The method of claim 11, wherein the charged powder moves dependent on the electric field for the charged powder to be dispensed on the object to be coated.

13. The method of claim 11, wherein supplying the powder to the warps includes:
displacing, by the actuating member, at least one of the framework and the trough for the warps to be positioned in the trough and loaded with the powder in the trough; and
moving, by the actuating member, the warps out of the trough.

14. The method of claim 11, wherein the action source includes impact force conduction, fluid power, sound wave or ultrasound.

15. The method of claim 11, wherein the device further comprises a plurality of woofs each having two ends combined with the framework for the woofs to be positioned within the boundary of the framework.

16. The method of claim 15, wherein the woofs and the warps form a mesh structure.

17. The method of claim 15, wherein at least one of the woofs and the warps are evenly distributed.
